(19) United States
(12) Patent Application Publication
(10) Pub. No.: US 2025/0192580 A1
(43) Pub. Date: Jun. 12, 2025

(54) SECONDARY BATTERY PROTECTION INTEGRATED CIRCUIT AND BATTERY DEVICE WITH ADJUSTABLE JUDGMENT VOLTAGE

(71) Applicants: Takeshi YAMAGUCHI, Tokyo (JP); Junji TAKESHITA, Tokyo (JP)

(72) Inventors: Takeshi YAMAGUCHI, Tokyo (JP); Junji TAKESHITA, Tokyo (JP)

(73) Assignee: MITSUMI ELECTRIC CO., LTD., Tokyo (JP)

(21) Appl. No.: 18/965,112

(22) Filed: Dec. 2, 2024

(30) Foreign Application Priority Data
Dec. 6, 2023 (JP) 2023-205827

(51) Int. Cl. H02J 7/00; H01M 10/42; H01M 50/574

(52) U.S. Cl. CPC H02J 7/00306; H01M 10/425; H01M 50/574; H02J 7/00302; H02J 7/0047; H02J 7/00712

(57) ABSTRACT

A secondary battery protection integrated circuit includes a plurality of terminals including a power supply terminal, a ground terminal, a selection terminal, and a control terminal; a selection circuit configured to change a judgment voltage according to a resistance value of a resistor that is configured to be externally coupled to the selection terminal; and a control circuit configured to output, from the control terminal, a signal to control charging or discharging of a secondary battery, based on comparing a power supply voltage between the power supply terminal and the ground terminal with the first judgment voltage.

### CROSS-REFERENCE TO RELATED APPLICATIONS

This application claims priority under 35 U.S.C. § 119 to Japanese Patent Application No. 2023-205827, filed Dec. 6, 2023, the contents of which are incorporated herein by reference.

### BACKGROUND

### 1. Technical Field

The present disclosure relates to a secondary battery protection integrated circuit and a battery device.

### 2. Description of the Related Art

Battery protection integrated circuits have been known to include a memory unit that stores characteristic setting data used for setting circuit characteristics of the battery protection integrated circuit; and a setting circuit that sets the circuit characteristics of the battery protection integrated circuit to circuit characteristics corresponding to the content of the characteristic setting data that is read from the memory unit. The circuit characteristics of the battery protection integrated circuit are modified when the characteristic setting data that is written to the memory unit is changed. In such a situation, a common circuit configuration can accommodate a plurality of different circuit characteristics.

### RELATED-ART DOCUMENT

### Patent Document

Patent Document 1: Japanese Patent No. 6520658

### SUMMARY

A secondary battery protection integrated circuit in a first aspect includes:
a plurality of terminals including a power supply terminal, a ground terminal, a selection terminal, and a control terminal;
a selection circuit configured to change a judgment voltage according to a resistance value of a resistor that is configured to be externally coupled to the selection terminal; and
a control circuit configured to output, from the control terminal, a signal to control charging or discharging of a secondary battery, based on comparing a power supply voltage between the power supply terminal and the ground terminal, with the judgment voltage.

A secondary battery protection integrated circuit in a second aspect includes:
a plurality of terminals including a power supply terminal, a ground terminal, a selection terminal, a monitor terminal, and a control terminal;
a selection circuit configured to change a judgment voltage according to a resistance value of a resistor that is configured to be externally coupled to the selection terminal; and
a control circuit configured to output, from the control terminal, a signal to control charging or discharging of a secondary battery, based on comparing, with the second judgment voltage, either a first potential difference between the monitor terminal and the power supply terminal or a second potential difference between the monitor terminal and the ground terminal.

A secondary battery protection integrated circuit in a third aspect includes:
a plurality of terminals including a power supply terminal, a ground terminal, a first selection terminal, a second selection terminal, a monitor terminal, and at least one control terminal;
a selection circuit configured to
   change at least one first judgment voltage according to a resistance value of a first resistor that is configured to be externally coupled to the first selection terminal, and
   change at least one second judgment voltage according to a resistance value of a second resistor that is configured to be externally coupled to the second selection terminal; and
a control circuit configured to
   output, from the control terminal, a first signal to control charging or discharging of a secondary battery, based on comparing a power supply voltage between the power supply terminal and the ground terminal, with the first judgment voltage, and
   output, from the control terminal, a second signal to control the charging or the discharging of the secondary battery, based on comparing, with the second judgment voltage, either a first potential difference between the monitor terminal and the power supply terminal or a second potential difference between the monitor terminal and the ground terminal.

A secondary battery protection integrated circuit in a fourth aspect includes:
a plurality of terminals including a power supply terminal, a ground terminal, a first selection terminal, a second selection terminal, a monitor terminal, and at least one control terminal;
a selection circuit configured to change at least one first judgment voltage and at least one second judgment voltage, according to a resistance value of a resistor that is configured to be externally coupled to the selection terminal; and
a control circuit configured to
   output, from the control terminal, a signal to control charging or discharging of a secondary battery, based on comparing a power supply voltage between the power supply terminal and the ground terminal, with the first judgment voltage, and
   output, from the control terminal, a signal to control the charging or the discharging of the secondary battery, based on comparing, with the second judgment voltage, either a first potential difference between the monitor terminal and the power supply terminal or a second potential difference between the monitor terminal and the ground terminal.

### BRIEF DESCRIPTION OF THE DRAWINGS

FIG. 1 is a circuit block diagram showing an example of a system including a secondary battery protection integrated circuit according to a first embodiment.

FIG. 2 is a circuit block diagram for describing a configuration example of a first selector in a first selection circuit.

FIG. 3 is a table for describing an operation example of the first selector.

FIG. 4 is a circuit block diagram for describing a configuration example of a second selector in a second selection circuit.

FIG. 5 is a table for describing an operation example of of the second selector.

FIG. 6 is a diagram showing a first example of the first selection circuit.

FIG. 7 is a diagram showing a first example of the second selection circuit.

FIG. 8 is a diagram showing a second example of the first selection circuit.

FIG. 9 is a diagram showing a third example of the first selection circuit.

FIG. 10 is a table showing an example of an adjustment result of an overcharge detection voltage Vdet1 according to a third example of the first selection circuit.

FIG. 11 is a circuit block diagram showing an example of the system including the secondary battery protection integrated circuit according to a second embodiment.

FIG. 12 is a circuit block diagram for describing a configuration example of a selector in a selection circuit.

FIG. 13 is a table for describing an operation example of of the selector.

FIG. 14 is a circuit block diagram showing an example of the system including the secondary battery protection integrated circuit according to a third embodiment.

FIG. 15 is a circuit block diagram showing an example of the system including the secondary battery protection integrated circuit in a modification of the third embodiment.

### DETAILED DESCRIPTION

The inventors of this application have recognized the following information in related art. For systems that write, to a memory, characteristic setting data for setting circuit characteristics such as judgment voltages, equipment and technology for reliably writing such data to the memory are required. In such a situation, it may be difficult to support the data that is written to the memory.

The present disclosure provides a secondary battery protection integrated circuit and a battery device that allows easy modification of circuit characteristics such as a judgment voltage.

Various embodiments of the present disclosure will be described below with reference to the drawings.

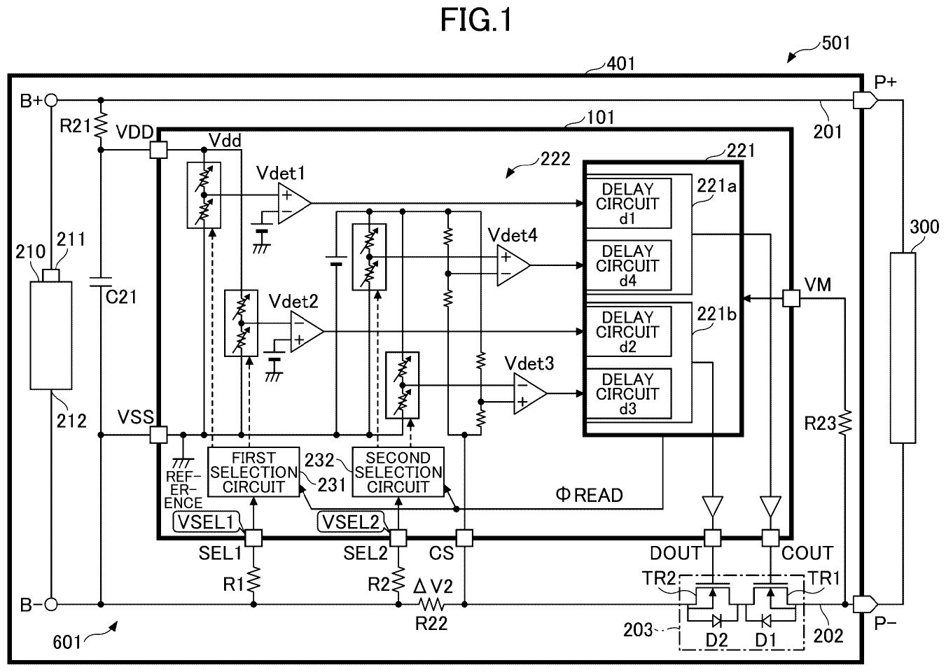

FIG. 1 is a circuit block diagram showing an example of a system including a secondary battery protection integrated circuit according to a first embodiment. A system 501 shown in FIG. 1 includes a battery device 401 and an electronic device 300.

The electronic device 300 is a device that is connected to the battery device 401. The electronic device 300 may be a charger that charges the battery device 401 or a load that operates by power supplied from the battery device 401. Specific examples of such a load include a cellular phone, a smartphone, a tablet device, an earphone, and the like. The electronic device 300 is not limited to the above devices.

The battery device 401 may be externally connected to the electronic device 300 or incorporated into the electronic device 300. The battery device 401 is, for example, a battery pack detachably accommodated in the electronic device 300. The battery device 401 can supply power to the electronic device 300 while being connected to the electronic device 300. The battery device 401 and the electronic device 300 are connected to each other via a plurality of terminals (a positive power supply terminal (terminal P+) and a negative power supply terminal (terminal P−)) shown in FIG. 1. For example, the terminal P+ and the terminal P− are electrically connected to a charger (electronic device 300) when the secondary battery 210 is charged.

The battery device 401 includes a secondary battery 210 and a battery protection device 601.

The secondary battery 210 is an example of a charge/discharge-capable battery. The secondary battery 210 supplies the power to the electronic device 300 that is connected to the terminal P+ and the terminal P−. The secondary battery 210 can be charged by the charger to be connected to the terminal P+ and the terminal P−. Specific examples of the secondary battery 210 include a lithium ion battery, a lithium polymer battery, and the like. The secondary battery 210 has a positive electrode 211 and a negative electrode 212.

The battery protection device 601 is an example of a secondary battery protection device that operates using the secondary battery 210 as a power source. The battery protection device 601 protects the secondary battery 210 from overcharging or the like by controlling the charging of the secondary battery 210. The battery protection device 601 also protects the secondary battery 210 from over-discharging or the like by controlling the discharge of the secondary battery 210. The battery protection device 601 includes, for example, the terminal P+, the terminal P−, a terminal B+, a terminal B−, resistors R1, R2, R21, R22, and R23, a capacitor C21, a power line 201, a ground line 202, a switch circuit 203, and a protection IC (Integrated Circuit) 101.

The battery protection device 601 is a component that includes, for example, a substrate on which at least the protection IC 101 and resistors R1 and R2 are mounted.

The terminal P+ is an example of a load positive terminal, to which the power line of the electronic device 300 is connected. The terminal P− is an example of a load negative terminal, to which the ground line of the electronic device 300 is connected. The terminal B+ is an example of a battery positive terminal, to which a positive electrode 211 of the secondary battery 210 is connected. The terminal B− is an example of the battery negative terminal, to which the negative electrode 212 of the secondary battery 210 is connected.

The terminal B+ and the terminal P+ are connected by the power line 201, which is a positive current path. The power line 201 is a power supply path connecting the terminal B+ and the terminal P+. The power line 201 functions as a charge path through which a charging current of the secondary battery 210 flows and a discharge path through which a discharging current of the secondary battery 210 flows.

The terminal B− and the terminal P− are connected by a ground line 202 as a negative-side current path. The ground line 202 is a power supply path connecting the terminal B− and the terminal P−. The ground line 202 functions as the charge path through which the charging current of the secondary battery 210 flows and the discharge path through which the discharging current of the secondary battery 210 flows.

The switch circuit 203 is provided on the ground line 202 between the terminal B− and the terminal P−. The switch circuit 203 includes, for example, a charge control transistor TR1 and a discharge control transistor TR2. The switch circuit 203 is a series circuit in which the charge control transistor TR1 and the discharge control transistor TR2 are connected in series. The charge control transistor TR1 is a semiconductor switching element that interrupts the charge path for the secondary battery 210. The discharge control transistor TR2 is a semiconductor switching element that interrupts the discharge path for the secondary battery 210.

In the case of FIG. 1, the charge control transistor TR1 interrupts the ground line 202 through which the charging current of the secondary battery 210 flows, and the discharge control transistor TR2 interrupts the ground line 202 through which the discharging current of the secondary battery 210 flows. The charge control transistor TR1 and the discharge control transistor TR2 are switching elements that switch between conducting and interrupting the ground line 202, and these transistors are inserted in series in the ground line 202. The charge control transistor TR1 and the discharge control transistor TR2 are, for example, N-channel MOSFETs (Metal Oxide Semiconductor Field Effect Transistors).

The charge control transistor TR1 has a parasitic diode D1 between a drain and a source, and a forward direction of the parasitic diode D1 is opposite to the direction of the charging current of the secondary battery 210. The charge control transistor TR1 is a switching element that is inserted in series in the ground line 202 such that the forward direction of the parasitic diode D1 matches the direction of a discharging current flow of the secondary battery 210.

The discharge control transistor TR2 has a parasitic diode D2 between a drain and a source, and a forward direction of the parasitic diode D2 is opposite to the direction of the discharging current of the secondary battery 210. The discharge control transistor TR2 is a switching element that is inserted in series in the ground line 202 such that the forward direction of the parasitic diode D2 matches the direction of a charging current flow of the secondary battery 210.

The protection IC 101 is an example of the secondary battery protection integrated circuit. The protection IC 101 operates using the secondary battery 210 as a power source.

The protection IC 101 has a function of protecting the secondary battery 210 from over-discharging or the like by controlling the switch circuit 203. For example, the protection IC 101 protects the secondary battery 210 from abnormal charging by turning off the charge control transistor TR1 upon detection of abnormal charging (such as overcharging or overcurrent in the charging direction (charging overcurrent) by the detection circuit 222. On the other hand, the protection IC 101 protects the secondary battery 210 from abnormal discharging by turning off the discharge control transistor TR2 upon abnormal discharging (such as over-discharging or overcurrent in the discharge direction (discharging overcurrent) by the detection circuit 222.

The protection IC 101 includes, for example, a charge control terminal (terminal COUT), a discharge control terminal (terminal DOUT), a detection terminal (terminal VM), a power supply terminal (terminal VDD), a ground terminal (terminal VSS), a current detection terminal (terminal CS), a first selection terminal (terminal SEL1), and a second selection terminal (terminal SEL2). Each of these terminals is, for example, an external connection terminal that connects an internal circuit of the protection IC 101 to the outside of the protection IC 101.

The terminal COUT is connected to a gate (control electrode) of the charge control transistor TR1, and outputs a signal to turn the charge control transistor TR1 on or off. The terminal DOUT is connected to a gate (control electrode) of the discharge control transistor TR2, and outputs a signal to turn the discharge control transistor TR2 on or off.

The terminal VM is an example of a monitor terminal used for monitoring a potential at the terminal P−, and is connected to the terminal P−. The terminal VM is used, for example, for monitoring whether the control circuit 221 in the protection IC 101 is connected to the electronic device 300 or the charger. The terminal VM is connected to the ground line 202 through the resistor R23, between the switch circuit 203 and the terminal P−. The terminal VM is electrically connected to the ground line 202 on an opposite side of the secondary battery 210 with respect to the switch circuit 203.

The terminal VM may be used to detect the charging overcurrent or discharging overcurrent that flows in the secondary battery 210, in the same manner as the terminal CS described later.

The terminal VDD is a power supply terminal of the protection IC 101, and is connected to the positive electrode 211 and the power line 201 of the secondary battery 210, through the resistor R21. The terminal VSS is a ground terminal of the protection IC 101, and is connected to the negative electrode 212 of the secondary battery 210. The capacitor C21 is connected between the terminal VDD and the terminal VSS. The terminal VSS is connected to the ground line 202 between the switch circuit 203 and the negative electrode 212. In this example, the terminal VSS is connected to the ground line 202 between the resistor R22 and the negative electrode 212.

The terminal CS is an example of the monitor terminal used for monitoring the charging current or discharging current that flows through the secondary battery 210, and is connected to the ground line 202 between the resistor R22 and the switch circuit 203 (the source of the discharge control transistor TR2). The resistor R22 is inserted in series in the ground line 202. One end of the resistor R22 is connected to the terminal VSS, and the other end of the resistor R22 is connected to the terminal CS. The detection circuit 222 in the protection IC 101 can detect the charging overcurrent or discharging overcurrent that flows through the secondary battery 210 by detecting a potential difference between the terminal VSS and the terminal CS. The resistor R22 functions as a sense resistor for detecting the current that flows through the secondary battery 210.

The terminal SEL1 is a terminal for selecting specifications of a first judgment voltage (in this example, each of an overcharge detection voltage Vdet1 and an over-discharge detection voltage Vdet2), and the resistor R1 is externally connected. The resistor R1 is an example of a first resistor provided outside the protection IC 101. The terminal SEL1 is connected to the ground line 202 via the resistor R1, between the switch circuit 203 and the negative electrode 212. In this example, the terminal SEL1 is connected to the ground line 202 between the resistor R22 and the negative electrode 212.

The terminal SEL2 is a terminal for selecting specifications of a second judgment voltage (in this example, each of a discharging overcurrent detection voltage Vdet3 and a charging overcurrent detection voltage Vdet4), and the resistor R2 is externally connected. The resistor R2 is an example of a second resistor provided outside the protection IC 101. The terminal SEL2 is connected to the ground line 202 via the resistor R2, between the switch circuit 203 and the negative electrode 212. In this example, the terminal SEL2 is connected to the ground line 202 between the resistor R22 and the negative electrode 212.

The protection IC 101 includes a detection circuit 222, a control circuit 221, a first selection circuit 231, and a second selection circuit 232.

The detection circuit 222 detects overcharging of the secondary battery 210 by monitoring the power supply voltage Vdd between the terminal VDD and the terminal VSS. The detection circuit 222 compares the power supply voltage Vdd with the overcharge detection voltage Vdet1, and generates an overcharge detection signal indicating that the overcharging of the secondary battery 210 is detected, when the power supply voltage Vdd is higher than the overcharge detection voltage Vdet1.

The detection circuit 222 detects charging overcurrent of the secondary battery 210 by monitoring a potential difference ΔV2 between the terminal VSS and the terminal CS (or the terminal VM). The detection circuit 222 compares the potential difference ΔV2 with the charging overcurrent detection voltage Vdet4, and generates a charging overcurrent detection signal indicating that the charging overcurrent of the secondary battery 210 is detected, when the potential difference ΔV2 is less than the charging overcurrent detection voltage Vdet4 with reference to the terminal VSS. In other words, the detection circuit 222 generates the charging overcurrent detection signal, when the voltage at the terminal CS (or the terminal VM) is less than the charging overcurrent detection voltage Vdet4 with reference to the terminal VSS.

The control circuit 221 includes a charge control circuit 221a that controls the charging of the secondary battery 210. When overcharging of the secondary battery 210 is detected continuously by the detection circuit 222 for a predetermined detection delay time d1, the charge control circuit 221a outputs, from the terminal COUT, a signal (e.g., a low-level gate control signal) to switch the charge control transistor TR1 from on to off. When charging overcurrent of the secondary battery 210 is continuously detected by the detection circuit 222 for a predetermined detection delay time d4, the charge control circuit 221a outputs, from the terminal COUT, a signal (e.g., a low-level gate control signal) to switch the charge control transistor TR1 from on to off.

By turning off the charge control transistor TR1, the control circuit 221 inhibits the current in the direction of charging the secondary battery 210 from flowing into the ground line 202. As a result, the charging of the secondary battery 210 is stopped, and thus the protection IC 101 can protect the secondary battery 210 from overcharging or charging overcurrent.

The detection circuit 222 detects over-discharging of the secondary battery 210 by monitoring the power supply voltage Vdd between the terminal VDD and the terminal VSS. The detection circuit 222 compares the power supply voltage Vdd with the over-discharge detection voltage Vdet2, and generates an over-discharge detection signal indicating that the over-discharging of the secondary battery 210 is detected, when the power supply voltage Vdd is less than the over-discharge detection voltage Vdet2.

The detection circuit 222 detects discharging overcurrent of the secondary battery 210 by monitoring the potential difference ΔV2 between the terminal VSS and the terminal CS (or the terminal VM). The detection circuit 222 compares the potential difference ΔV2 with the discharging overcurrent detection voltage Vdet3, and generates a discharging overcurrent detection signal indicating that the discharging overcurrent of the secondary battery 210 is detected, when the potential difference ΔV2 is higher than the discharging overcurrent detection voltage Vdet3 with reference to the terminal VSS. In other words, the detection circuit 222 generates the discharging overcurrent detection signal when the voltage at the terminal CS (or the terminal VM) is higher than the discharging overcurrent detection voltage Vdet3 with reference to the terminal VSS.

The control circuit 221 includes a discharge control circuit 221b that controls discharging of the secondary battery 210. The discharge control circuit 221b outputs, from the terminal DOUT, a signal (e.g., a low-level gate control signal) to switch the discharge control transistor TR2 from on to off when over-discharging of the secondary battery 210 is continuously detected by the detection circuit 222 for a predetermined detection delay time d2. The discharge control circuit 221b outputs, from the terminal DOUT, a signal (e.g., a low-level gate control signal) to switch the discharge control transistor TR2 from on to off when discharging overcurrent of the secondary battery 210 is continuously detected by the detection circuit 222 for a predetermined detection delay time d3.

By turning off the discharge control transistor TR2, the control circuit 221 inhibits the current in the direction of discharging the secondary battery 210 from flowing into the ground line 202. As a result, the discharging of the secondary battery 210 is stopped, so that the protection IC 101 can protect the secondary battery 210 from over-discharging or discharging overcurrent.

The first selection circuit 231 changes the overcharge detection voltage Vdet1 according to a resistance value of the resistor R1 that is externally connected to the terminal SEL1. In this arrangement, when the resistance value of the resistor R1 externally connected to the protection IC 101 is changed, the overcharge detection voltage Vdet1 can be easily changed. By using the resistor R1 externally connected to the protection IC 101, the specifications of the overcharge detection voltage Vdet1 can be easily changed while the protection IC 101 is mounted on the substrate.

The first selection circuit 231 changes the overcharge detection voltage Vdet1 to a voltage value corresponding to the resistance value of the resistor R1 externally connected to the terminal SEL1, in accordance with a correspondence relationship that is preset in the first selection circuit 231, for example. In this case, when the resistance value of the resistor R1 externally connected to the terminal SEL1 is changed to a specified resistance value, the protection IC 101 can be used in common with products (for example, the battery protection device 601, the battery device 401, and the like) having different required specifications of the overcharge detection voltage Vdet1. As a result, for example, inventory management can be simplified and production man-hours can be reduced.

The first selection circuit 231 may have a first potential changing circuit that changes the potential at the terminal SEL1 (a first selection potential VSEL1), according to the resistance value of the resistor R1 externally connected to the terminal SEL1, and the first selection circuit 231 may change the overcharge detection voltage Vdet1 to a voltage value corresponding to the first selection potential VSEL1. In this arrangement, when the resistance value of the resistor R1 externally connected to the protection IC 101 is changed, the first selection potential VSEL1 is changed, so that the overcharge detection voltage Vdet1 can be easily changed. The first selection circuit 231 changes the overcharge detection voltage Vdet1 to a voltage value corresponding to the first selection potential VSEL1, in accordance with a correspondence relationship that is preset in the first selection circuit 231, for example.

The first selection circuit 231 changes the over-discharge detection voltage Vdet2 according to the resistance value of the resistor R1 externally connected to the terminal SEL1. The case where the first selection circuit 231 changes the over-discharge detection voltage Vdet2 is similar to the case where the first selection circuit 231 changes the overcharge detection voltage Vdet1, and accordingly, the description thereof is omitted by referring to the above description.

The second selection circuit 232 changes the charging overcurrent detection voltage Vdet4 according to a resistance value of the resistor R2 externally connected to the terminal SEL2. In this arrangement, the charging overcurrent detection voltage Vdet4 can be changed by changing the resistance value of the resistor R2 externally connected to the protection IC 101. By using the resistor R2 externally connected to the protection IC 101, the specifications of the charging overcurrent detection voltage Vdet4 can be easily changed even when the protection IC 101 is mounted on the substrate.

The second selection circuit 232 changes the charging overcurrent detection voltage Vdet4 to a voltage value corresponding to the resistance value of the resistor R2 externally connected to the terminal SEL2, in accordance with a correspondence relationship that is preset in the second selection circuit 232, for example. In this case, when the resistance value of the resistor R2 externally connected to the terminal SEL2 is changed to a specified resistance value, the protection IC 101 can be used in common with products (such as the battery protection device 601 and the battery device 401) having different required specifications of the charging overcurrent detection voltage Vdet4. As a result, for example, inventory management can be simplified and production man-hours can be reduced.

The second selection circuit 232 may have a second potential changing circuit that changes the potential at the terminal SEL2 (a second selection potential VSEL2), according to the resistance value of the resistor R2 externally connected to the terminal SEL2, and the second selection circuit 232 may change the charging overcurrent detection voltage Vdet4 to a voltage value corresponding to the second selection potential VSEL2. In this arrangement, when the resistance value of the resistor R2 externally connected to the protection IC 101 is changed, the second selection potential VSEL2 changes, so that the charging overcurrent detection voltage Vdet4 can be easily changed. The second selection circuit 232 changes the charging overcurrent detection voltage Vdet4 to a voltage value corresponding to the second selection potential VSEL2, in accordance with a correspondence relationship that is preset in the second selection circuit 232, for example.

The second selection circuit 232 changes the discharging overcurrent detection voltage Vdet3, according to the resistance value of the resistor R2 externally connected to the terminal SEL2. The case where the second selection circuit 232 changes the discharging overcurrent detection voltage Vdet3 is similar to the case where the second selection circuit 232 changes the charging overcurrent detection voltage Vdet4, and accordingly, the description thereof is omitted by referring to the above description.

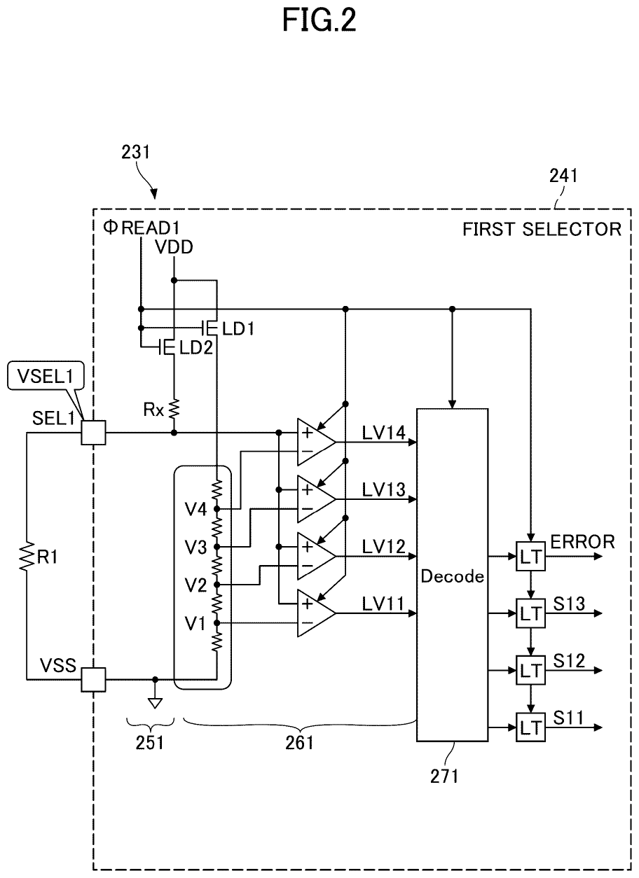

FIG. 2 is a diagram for describing a configuration example of the first selector in the first selection circuit. The first selection circuit 231 includes a first selector 241 as a component. When a first read signal ΦREAD1 is in an active state, the first selector 241 selects one selection signal corresponding to the resistance value of the resistor R1 that is externally connected to the terminal SEL1, from among a plurality of different selection signals S11, S12, and S13. The different selection signals S11, S12, and S13 are selection signal candidates that are preset in a first decoder 271 in the first selector 241.

The first selector 241 includes a first potential changing circuit 251 that changes the potential (first selection potential VSEL1) at the terminal SEL1 by using a reference resistor Rx and a switch LD2 in accordance with the resistance value of the resistor R1 externally connected to the terminal SEL1. The reference resistor Rx is inserted in series in a current path between the first selection terminal SEL1 and the terminal VDD. When the switch LD2 is turned on in response to the first read signal ΦREAD1, the first selection terminal SEL1 is pulled up to the terminal VDD through the reference resistor Rx, so that the first selection potential VSEL1 changes according to the resistance value of the resistor R1.

The first selector 241 includes a first encoder 261. The first encoder 261 encodes the first selection potential VSEL1, and outputs codes (LV11, LV12, LV13, and LV14) corresponding to the resistance value of the resistor R1. The first encoder 261 includes a plurality of resistors in series that are inserted in series between the terminal VDD and the terminal VSS, and includes a plurality of comparators that compare the first selection potential VSEL1 with respective potentials V1, V2, V3, and V4. When the switch LD1 is turned on in response to the first read signal ΦREAD1, the different potentials V1, V2, V3, and V4 are generated by voltage division using the resistors in series.

The first selector 241 includes a first decoder 271. The first decoder 271 is a circuit that converts one among the codes (LV11, LV12, LV13, and LV14) into a given signal among selection signals and an error signal ERROR. The first decoder 271 outputs the given signal among selection signals S11, S12, and S13 and the error signal ERROR, as a result of selecting one among the codes (LV11, LV12, LV13, and LV14). The given signal, among the selection signals S11, S12, and S13 and the error signal ERROR, that is output from the first decoder 271 is held in a latch circuit LT.

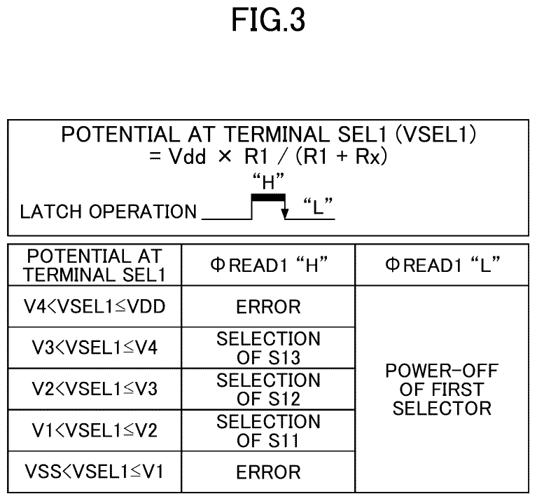

FIG. 3 is a table for describing an operation example of the first selector. The first selector 241 becomes operational when the first read signal ΦREAD1 is in the active state (in this example, at a high level “H”). In an operational state, the first selector 241 outputs, from the first decoder 271, a result of selecting the first selection potential VSEL1 that corresponds to the resistance value of the resistor R1 externally connected to the terminal SEL1. When the first read signal ΦREAD1 transitions from the active state to an inactive state (in this example, at a low level “L”) in the first selector 241, a selection result is held in the latch circuit LT.

For example, when the first selection potential VSEL1 is higher than the potential at the terminal VSS and equal to or less than the potential V1, or higher than the potential V4 and equal to or less than the potential at the terminal VDD, the first selector 241 selects the error signal ERROR, and the error signal ERROR is held in the latch circuit LT. When the first selection potential VSEL1 is higher than the potential V1 and equal to or less than the potential V2, the first selector 241 holds a selected selection signal S11 in the latch circuit LT. In this arrangement, the first selector 241 selects a given selection signal according to the correspondence relationship shown in FIG. 3, and the given selection signal is held in the latch circuit LT.

The current supplied to the first selector 241 is cut off when the first read signal ΦREAD1 is in the inactive state. As a result, current consumption of the first selector 241 is reduced, and power consumption of the protection IC 101 is suppressed. In the case of FIG. 2, when the first read signal ΦREAD1 is in the inactive state, the switches LD1 and LD2 are turned off, so that the current flowing through the reference resistor Rx and the resistors in series is reduced.

For example, the control circuit 221 activates the first read signal ΦREAD1 when over-discharging of the secondary battery 210 is detected, and deactivates the first read signal ΦREAD1 when over-discharging of the secondary battery 210 is not detected. As a result, the first selector 241 operates only during a specific period in which over-discharging is detected, and stops during other periods. As a result, the the effect of reducing power consumption in the protection IC 101 is improved. When over-discharging is detected, the first read signal ΦREAD1 can be set to a pulse signal having an active state shorter than a time period during which over-discharging is detected. As a result, the effect of reducing power consumption in the protection IC 101 can be effectively improved.

The first selection circuit 231 outputs the error signal ERROR when the resistance value of the resistor R1 is greater than a first predetermined value (in this example, when the first selection potential VSEL1 is higher than the potential V4 and equal to or less than the potential at the terminal VDD). Alternatively, the first selection circuit 231 outputs the error signal ERROR when the resistance value of the resistor R1 is less than a second predetermined value (in this example, when the first selection potential VSEL1 is higher than the potential at the terminal VSS and equal to or less than the potential V1). In this case, it is possible to detect an abnormality due to a missing resistor R1 to be externally connected to the protection IC 101; or a short circuit or the like of the terminal SEL1.

For example, when the error signal ERROR is output, the control circuit 221 outputs a signal from the terminal COUT to stop charging of the secondary battery 210; a signal from the terminal DOUT to stop discharging of the secondary battery 210; or both. In this arrangement, safety is ensured against abnormalities of the resistor R1.

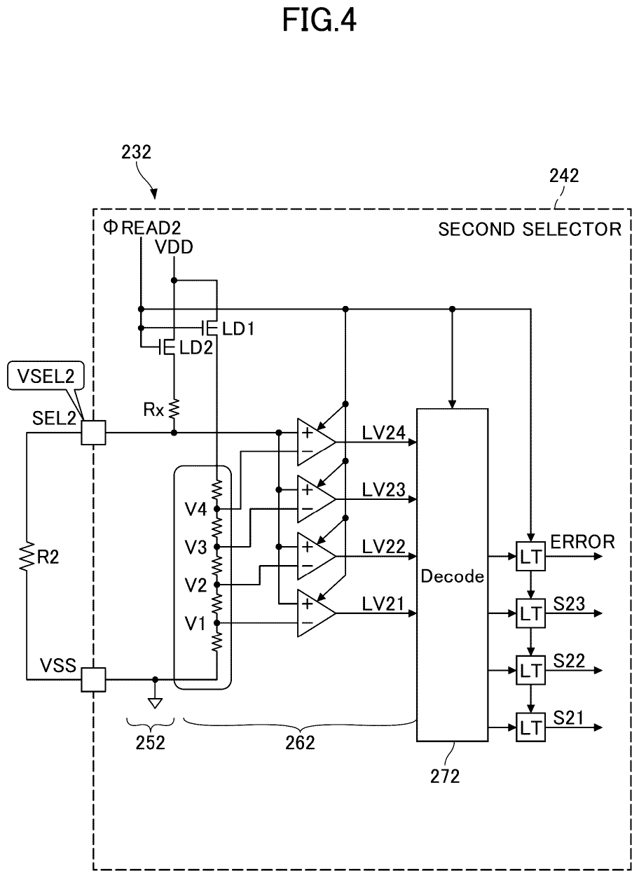

FIG. 4 is a diagram for describing a configuration example of the second selector in the second selection circuit. The second selection circuit 232 includes a second selector 242 as a component. When a second read signal ΦREAD2 is in an active state, the second selector 242 selects one selection signal that corresponds to the resistance value of the resistor R2 externally connected to the terminal SEL2, from among a plurality of different selection signals S21, S22, and S23. The different selection signals S21, S22, and S23 are selection signal candidates that are preset in a second decoder 272 in the second selector 242. The second read signal ΦREAD2 may be the same as or different from the first read signal ΦREAD1.

The second selector 242 includes a second potential changing circuit 252 that changes the potential at the terminal SEL2 (a second selection potential VSEL2) by using the reference resistor Rx and a switch LD2, in accordance with the resistance value of the resistor R2 externally connected to the terminal SEL2. The reference resistor Rx is inserted in series in a current path between the second selection terminal SEL2 and the terminal VDD. When the switch LD2 is turned on in response to the second read signal ΦREAD2, the second selection terminal SEL2 is pulled up to the terminal VDD through the reference resistor Rx, so that the second selection potential VSEL2 changes according to the resistance value of the resistor R2.

The second selector 242 includes a second encoder 262. The second encoder 262 encodes the second selection potential VSEL2, and outputs codes (LV21, LV22, LV23, and LV24) corresponding to the resistance value of the resistor R2. The second encoder 262 has a plurality of resistors in series that are inserted in series between the terminal VDD and the terminal VSS. A plurality of comparators that compare the second selection potential VSEL2 with respective potentials V1, V2, V3, and V4. When the switch LD1 is turned on in response to the second read signal ΦREAD2, the different potentials V1, V2, V3, and V4 are generated by voltage division using the resistors in series.

The second selector 242 includes a second decoder 272. The second decoder 272 is a circuit that converts one among the codes (LV21, LV22, LV23, and LV24) into a given signal among selection signals and an error signal ERROR. The second decoder 272 outputs the given signal among selection signals S21, S22, and S23 and the error signal ERROR, as a result of selecting one among decoding the code (LV21, LV22, LV23, and LV24). The given signal, among the selection signals S21, S22, S23 and the error signal ERROR, that is output from the second decoder 272 is held in the latch circuit LT.

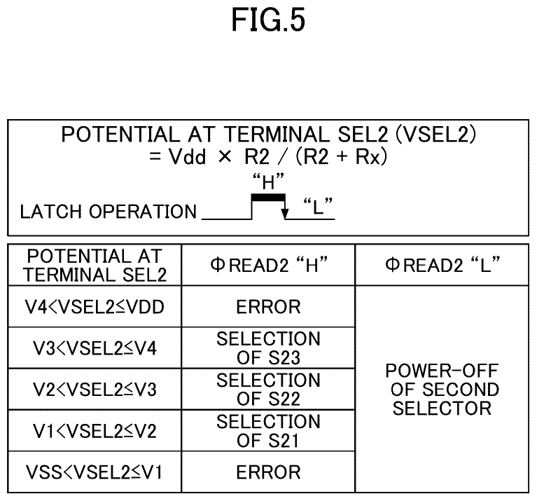

FIG. 5 is a table for describing an operation example of the second selector. The second selector 242 becomes operational when the second read signal ΦREAD2 is in the active state (in this example, at a high level “H”). In an operational state, the second selector 242 outputs, from the second decoder 272, a result of selecting the second selection potential VSEL2 that corresponds to the resistance value of the resistor R2 externally connected to the terminal SEL2. When the second read signal ΦREAD2 transitions from the active state to an inactive state (in this example, a low level “L”) in the second selector 242, a selection result is held in the latch circuit LT.

For example, when the second selection potential VSEL2 is higher than the potential at the terminal VSS and equal to or less than the potential V1, or higher than the potential V4 and equal to or less than the potential at the terminal VDD, the second selector 242 selects the error signal ERROR, and the error signal ERROR is held in the latch circuit LT. When the second selection potential VSEL2 is higher than the potential V1 and equal to or less than the potential V2, the second selector 242 holds a selected selection signal S21 in the latch circuit LT. In this arrangement, the second selector 242 selects a given selection signal according to the correspondence relationship shown in FIG. 5, and the selection signal is held in the latch circuit LT.

The current supplied to the second selector 242 is cut off when the second read signal ΦREAD2 is in the inactive state. As a result, current consumption of the second selector 242 is reduced, and power consumption of the protection IC 101 is suppressed. In the case of FIG. 4, when the second read signal ΦREAD2 is in the inactive state, the switches LD1 and LD2 are turned off, and the current flowing through the reference resistor Rx and the resistors in series is reduced.

For example, the control circuit 221 activates the second read signal ΦREAD2 when over-discharging of the secondary battery 210 is detected, and deactivates the second read signal ΦREAD2 when over-discharging of the secondary battery 210 is not detected. In this arrangement, the second selector 242 operates only during a specific period in which the over-discharging is detected, and stops during other periods, and thus the effect of reducing power consumption in the protection IC 101 is improved. When over-discharging is detected, the second read signal ΦREAD2 can be set as a pulse signal having an active state that is shorter than a time period during which over-discharging is detected. As a result, the effect of reducing power consumption in the protection IC 101 can be effectively improved.

The second selection circuit 232 outputs the error signal ERROR when the resistance value of the resistor R2 is higher than a first predetermined value (in this example, when the second selection potential VSEL2 is higher than the potential V4 and equal to or less than the potential at the terminal VDD). Alternatively, the second selection circuit 232 outputs the error signal ERROR when the resistance value of the resistor R2 is less than a second predetermined value (in this example, when the second selection potential VSEL2 is higher than the potential at the terminal VSS and equal to or less than the potential V1). As a result, it is possible to detect an abnormality due to a missing resistor R2 to be externally connected to the protection IC 101 or a short circuit or the like of the terminal SEL2.

For example, when the error signal ERROR is output, the control circuit 221 outputs a signal from the terminal COUT to stop charging of the secondary battery 210; a signal from the terminal DOUT to stop discharging of the secondary battery 210; or both. In this arrangement, safety is ensured against abnormalities of the resistor R2.

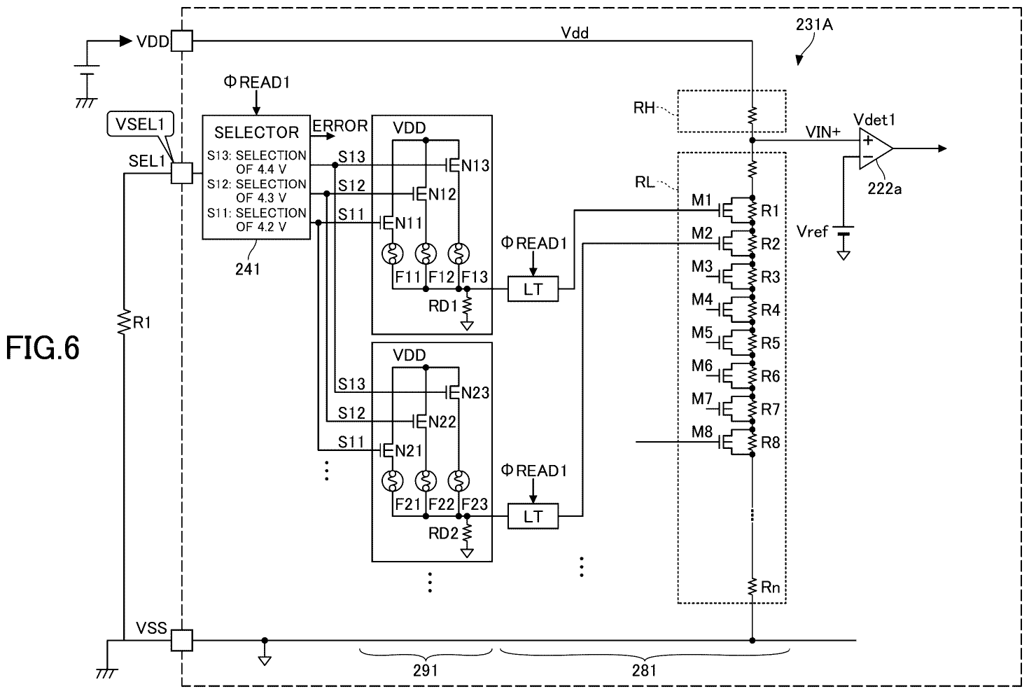

FIG. 6 is a configuration diagram showing a first example of the first selection circuit. The first selection circuit 231 and the second selection circuit 232 have the same configuration and function, and the description of the first example of the second selection circuit 232 is omitted by referring to the description of the first example of the first selection circuit 231. A first selection circuit 231A shown in FIG. 6 is a first example of the first selection circuit 231.

When k is an integer of 2 or more, the first selection circuit 231A adjusts the overcharge detection voltage Vdet1 to any one of k different voltage values. FIG. 6 illustrates a case where k is 3. The first selection circuit 231A includes a first selector 241, a trimming circuit 291, and an adjustment circuit 281.

When the first read signal ΦREAD1 is in the active state, the first selector 241 selects one selection signal corresponding to the resistance value of the resistor R1 externally connected to the terminal SEL1, from among k (in this example, three) different selection signals S11, S12, and S13. The trimming circuit 291 has a plurality of (=k×n) trimming elements. Here, n is an integer of 2 or more, and in this example, k=3 is given. The first selector 241 selects a plurality of trimming elements corresponding to the resistance value (in this example, the first selection potential VSEL1) of the resistor R1, from among trimming elements F11, F12, F13, F21, F22, F23, . . . , Fn1, Fn2, and Fn3 in the trimming circuit 291.

The trimming circuit 291 has the plurality (=3×n) of trimming elements F1l, F12, F13, F21, F22, F23, . . . , Fn1, Fn2, and Fn3; a plurality (=3×n) of switching elements N11, N12, N13, N21, N22, N23, . . . , Nn1, Nn2, and Nn3; and n resistors RD1, RD2, . . . , and RDn. The plurality of trimming elements F11, F12, F13, F21, F22, F23, . . . , Fn1, Fn2, and Fn3 are connected in series with corresponding switching elements N11, N12, N13, N21, N22, N23, . . . , Nn1, Nn2, and Nn3. Each trimming element includes, for example, a fuse element that can be cut by laser emitted from the outside of the protection IC 101. The trimming circuit 291 may be an OTP (One Time Programmable) memory.

The adjustment circuit 281 adjusts the overcharge detection voltage Vdet1 to a voltage value corresponding to a trimming state of each of trimming elements that are selected by the first selector 241. The adjustment circuit 281 has n latch circuits LT that hold the trimming states of the respective trimming elements; a resistor RH; resistors RL (n trimming resistors R1 to Rn); and n switching elements M1 to Mn.

In the adjustment circuit 281, when the first read signal ΦREAD1 transitions from the active state to the inactive state (in this example, the low level “L”), the trimming state of each of the trimming elements selected by the first selector 241 is held in a given latch circuit LT. Each of given latch circuits LT outputs the signal indicating a holding state of the trimming state.

The n switching elements M1 to Mn are connected in parallel with the corresponding trimming resistors R1 to Rn, and are turned on or off in response to outputs of the corresponding latch circuits LT.

When the power supply voltage Vdd rises, a detection voltage VIN+ that is obtained by dividing the power supply voltage Vdd using the resistors RH and RL rises. When the detection voltage VIN+ exceeds a reference voltage Vref, the output of a comparator 222a in the detection circuit 222 is inverted. The power supply voltage Vdd when the output of comparator is inverted is set as the overcharge detection voltage Vdet1.

FIG. 6 illustrates a case where trimming elements corresponding to one selection signal selected by the first selector 241 are selected among the selection signals S11, S12, and S13. The resistance value of the resistor RL changes according to trimming states of selected trimming elements, and thus the overcharge detection voltage Vdet1 is adjusted to any one of k voltage values (in this example, three voltages).

When the selection signal S11 is selected by the first selector 241, the overcharge detection voltage Vdet1 is adjusted to, for example, 4.2 volts. When the selection signal S11 is selected, only switching elements N11, N21, . . . , and Nn1, corresponding to the selection signal S11, are turned on, so that trimming elements F1l, F21, . . . , and Fn1 are selected (enabled). The trimming elements F1l, F21, . . . , and Fn1 selected by the selection signal S11 are trimmed such that the overcharge detection voltage Vdet1 becomes 4.2 volts. The resistance value of the resistor RL is adjusted by the adjustment circuit 281 to a resistance value corresponding to the trimming states of the trimming elements F11, F21, . . . , and Fn1. As a result, the overcharge detection voltage Vdet1 is finely adjusted to 4.2 volts. When the resistance value of the resistor RL is defined as RL1 under a condition in which the overcharge detection voltage Vdet1 is 4.2 volts, the overcharge detection voltage Vdet1 is expressed by “Vdet1=(RH+RL1)×Vref/RL1.”

When the selection signal S12 is selected by the first selector 241, the overcharge detection voltage Vdet1 is adjusted to, for example, 4.3 volts. When the selection signal S12 is selected, only switching elements N12, N22, . . . , and Nn2, corresponding to the selection signal S12, are turned on, so that the trimming elements F12, F22, . . . , and Fn2 are selected (enabled). The trimming elements F12, F22, . . . , and Fn2 selected by the selection signal S12 are trimmed such that the overcharge detection voltage Vdet1 becomes 4.3 volts. The resistance value of the resistor RL is adjusted by the adjustment circuit 281 to a resistance value corresponding to the trimming states of the trimming elements F12, F22, . . . , and Fn2. As a result, the overcharge detection voltage Vdet1 is finely adjusted to 4.3 volts. When the resistance value of the resistor RL is defined as RL2 under a condition in which the overcharge detection voltage Vdet1 is 4.3 volts, the overcharge detection voltage Vdet1 is expressed by “Vdet1=(RH+RL2)×Vref/RL2.”

When the selection signal S13 is selected by the first selector 241, the overcharge detection voltage Vdet1 is adjusted to, for example, 4.4 volts. When the selection signal S13 is selected, only switching elements N13, N23, . . . , and Nn3, corresponding to the selection signal S13, are turned on, so that trimming elements F13, F23, . . . , and Fn3 are selected (enabled). The trimming elements F13, F23, . . . , and Fn3 selected by the selection signal S13 are trimmed such that the overcharge detection voltage Vdet1 becomes 4.4 volts. The resistance value of the resistor RL is adjusted by the adjustment circuit 281 to a resistance value corresponding to the trimming states of the trimming elements F13, F23, . . . , and Fn3. As a result, the overcharge detection voltage Vdet1 is finely adjusted to 4.4 volts. When the resistance value of the resistor RL is defined as RL3 under a condition in which the overcharge detection voltage Vdet1 is 4.4 volts, the overcharge detection voltage Vdet1 is expressed by “Vdet1=(RH+RL3)×Vref/RL3.”

The first selection circuit 231A adjusts the over-discharge detection voltage Vdet2, similarly to the case described above in which the overcharge detection voltage Vdet1 is adjusted. The second selection circuit 232 adjusts the discharging overcurrent detection voltage Vdet3 or the charging overcurrent detection voltage Vdet4, similarly to the case described above in which the first selection circuit 231A adjusts the overcharge detection voltage Vdet1.

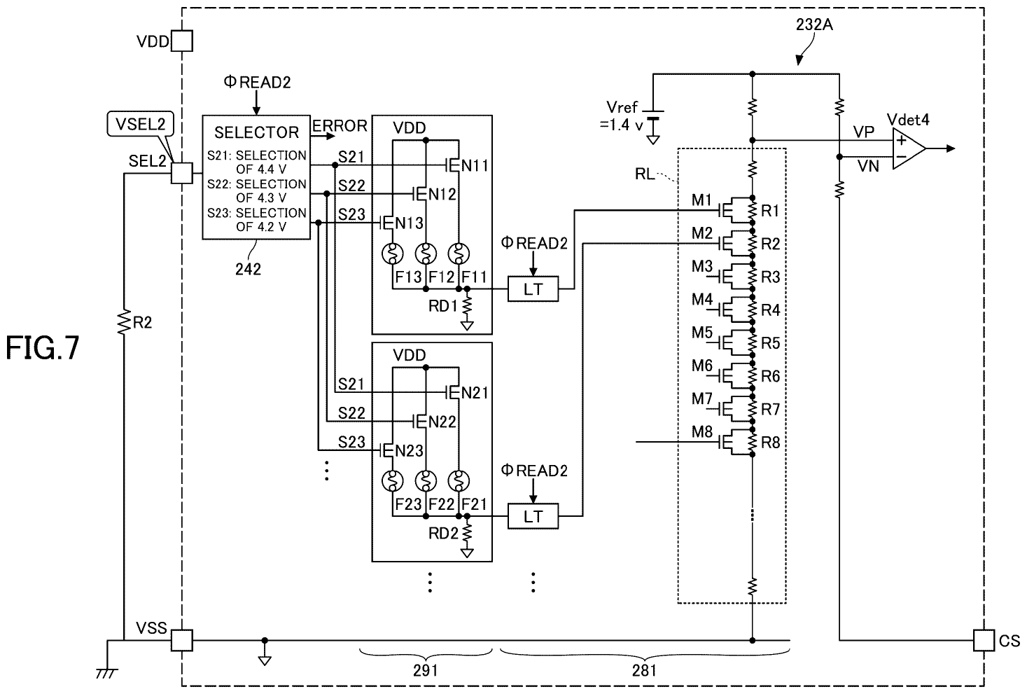

For example, the second selection circuit 232 adjusts the charging overcurrent detection voltage Vdet4 by the configuration shown in FIG. 7. A second selection circuit 232A shown in FIG. 7 is an example of the second selection circuit 232.

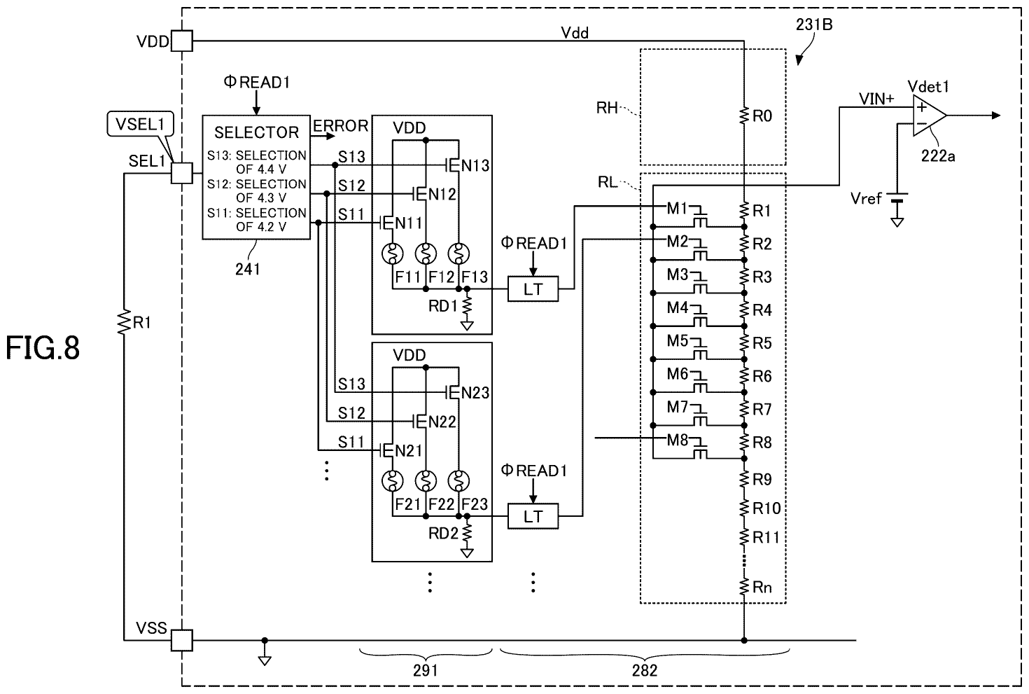

FIG. 8 is a block diagram showing a second example of the first selection circuit. The first selection circuit 231 and the second selection circuit 232 have the same configuration and function, and the description of the second example of the second selection circuit 232 is omitted by referring to the description of the second example of the first selection circuit 231. A first selection circuit 231B shown in FIG. 8 is a second example of the first selection circuit 231. For the first selection circuit 231B, the same configuration as that of the first example of the first selection circuit 231 is explained by referring to the description above. The first selection circuit 231B includes a first selector 241, a trimming circuit 291, and an adjustment circuit 282. The first selector 241 and the trimming circuit 291 may be the same as those of the first selection circuit 231A.

The adjustment circuit 282 adjusts the overcharge detection voltage Vdet1 to a voltage value corresponding to trimming states of trimming elements that are selected by the first selector 241. The adjustment circuit 282 has n latch circuits LT that holds trimming states of respective trimming elements; a resistor RH (resistor R0); resistors RL (n trimming resistors R1 to Rn); and n switching elements M1 to Mn. Here, n is an integer of 2 or more.

In the adjustment circuit 282, when the first read signal ΦREAD1 transitions from the active state to the inactive state (in this example, the low level “L”), the trimming states of the trimming elements selected by the first selector 241 are held in the respective latch circuits LT. The latch circuits LT output signals each of which indicates a holding state.

One ends of n switching elements M1 to Mn are connected to one ends of corresponding trimming resistors R1 to Rn. The n switching elements M1 to Mn are turned on or off in response to the outputs of the corresponding latch circuits LT. The other ends of the n switching elements M1 to Mn are connected in common with one another and are connected to a non-inverting input terminal of the comparator 222a.

The first selection circuit 231B finely adjusts the overcharge detection voltage Vdet1, similarly to the first selection circuit 231A described above. The first selection circuit 231A adjusts the resistance value of the resistor RL by shorting one or more trimming resistors, while the first selection circuit 231B adjusts the resistance value of the resistor RL by selecting one or more nodes between trimming resistors. Similarly to the first selection circuit 231A, in the case of the first selection circuit 231B, the overcharge detection voltage Vdet1 is expressed by “Vdet1=(RH+RL)×Vref/RL.”

The first selection circuit 231B adjusts the over-discharge detection voltage Vdet2, similarly to the case described above in which the overcharge detection voltage Vdet1 is adjusted. The second selection circuit 232 adjusts the discharging overcurrent detection voltage Vdet3 or the charging overcurrent detection voltage Vdet4, similarly to the case described above in which the first selection circuit 231B adjusts the overcharge detection voltage Vdet1.

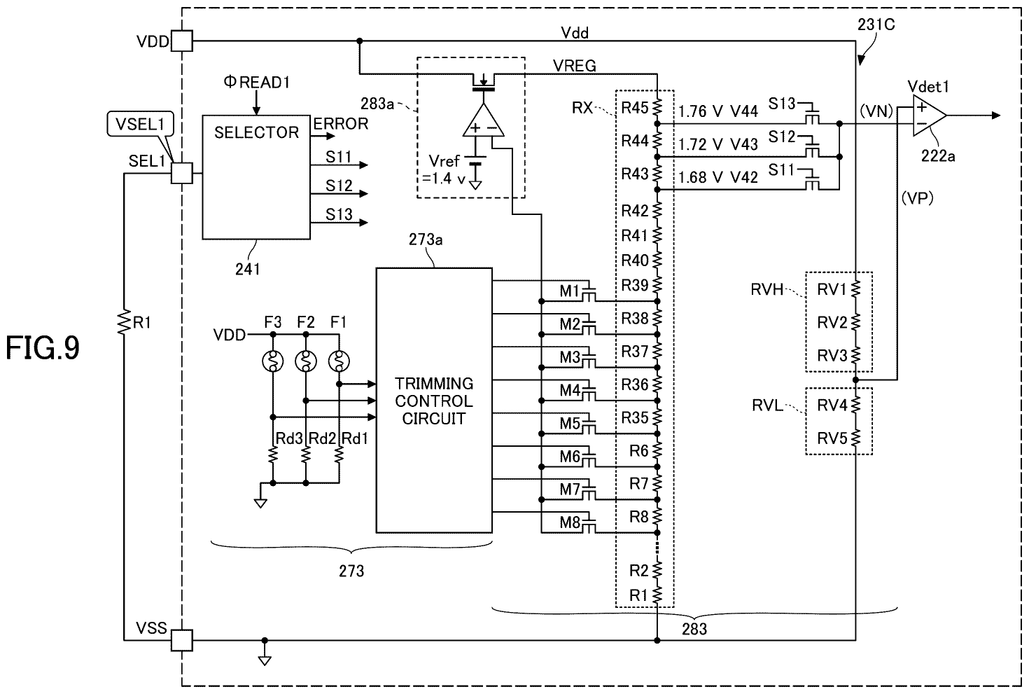

FIG. 9 is a configuration diagram showing a third example of the first selection circuit. The first selection circuit 231 and the second selection circuit 232 have the same configuration and function, and the description of the third example of the second selection circuit 232 is omitted by referring to the description of the third example of the first selection circuit 231. A first selection circuit 231C shown in FIG. 9 is the third example of the first selection circuit 231. For the first selection circuit 231C, the same configuration as that of each of the first example and the second example of the first selection circuit 231 is incorporated in the description above.

When k is an integer of 2 or more, the first selection circuit 231C adjusts the overcharge detection voltage Vdet1 to any one of k voltage values. FIG. 9 illustrates a case where k is 3. The first selection circuit 231C includes a first selector 241, a trimming circuit 273, and an adjustment circuit 283. The first selector 241 may be the same as the case of the first selection circuit 231A.

When the first read signal ΦREAD1 is in the active state, the first selector 241 selects one selection signal, corresponding to the resistance value of the resistor R1 externally connected to the terminal SEL1, from among k (in this example, three) different selection signals S11, S12, and S13. The first selector 241 selects a potential corresponding to the selected one selection signal, from among k (in this example, three) different potentials V42, V43, and V44, and sets the selected potential to a potential VN on the reference potential side of the comparator 222a. The first selection circuit 231C adjusts the overcharge detection voltage Vdet1 to one of k (in this example, three) voltage values by setting the potential VN based on the selected one selection signal.

The trimming circuit 273 has k (in this example, three) trimming elements F1, F2, and F3; k (in this example, three) resistors Rd1, Rd2, and Rd3; and a trimming control circuit 273a. The resistors Rd1, Rd2, and Rd3 are connected in series with the corresponding trimming elements F1, F2, and F3. The trimming control circuit 273a decodes trimming states of the k (in this example, three) trimming elements F1, F2, and F3, into 2^{k} (in this example, eight) signals.

The adjustment circuit 283 adjusts the overcharge detection voltage Vdet1 to a voltage value corresponding to one selection signal selected by the first selector 241. The adjustment circuit 283 has resistors RVH (fixed resistors RV1, RV2, and RV3); resistors RVL (fixed resistors RV4 and RV5); resistors RX (m trimming resistors R1 to Rm); 2^{k} (in this example, eight) switching elements M1 to M8; and a regulator 283a. Here, m is an integer equal to or greater than 2.

In the first selection circuit 231C, one or more resistors RX are first adjusted such that an output voltage VREG of the regulator 28 becomes a predetermined target value (e.g., 1.80 volts). The resistors RX are adjusted using the switching elements M1 to M8 that are turned on or off in accordance with the trimming states of the trimming elements F1, F2, and F3. In this arrangement, values of potentials V42, V43, and V44 are determined.

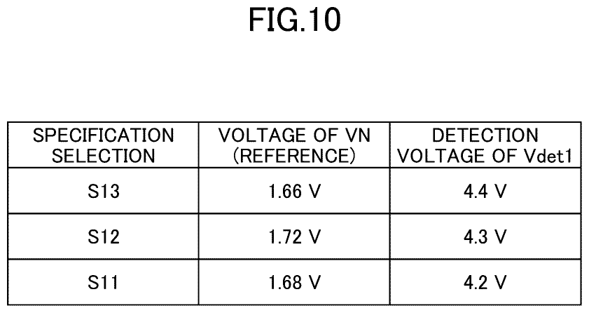

The first selector 241 selects a potential corresponding to one of the selected selection signals, from among the different potentials V42, V43, and V44, and sets the selected potential as the potential VN (potential at the inverting input terminal) on the reference potential side of the comparator 222a. The potential VP (potential of the non-inverting input terminal) on the reference side of the comparator 222a is a fixed value (=Vdd×RVL/(RVH+RVL)). As a result, the overcharge detection voltage Vdet1 is adjusted based on the selected selection signal as shown in FIG. 10.

The first selection circuit 231C adjusts the over-discharge detection voltage Vdet2, similarly to the case described above in which the overcharge detection voltage Vdet1 is adjusted. The second selection circuit 232 adjusts the discharging overcurrent detection voltage Vdet3 or the charging overcurrent detection voltage Vdet4, similarly to the case described above in which the first selection circuit 231C adjusts the overcharge detection voltage Vdet1.

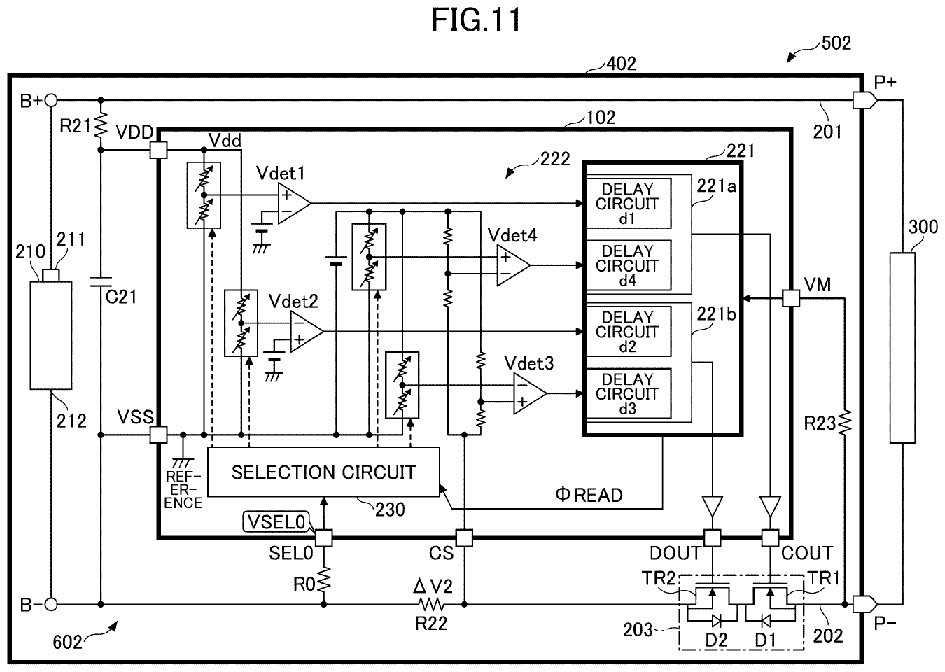

FIG. 11 is a circuit block diagram showing an example of a system including the secondary battery protection integrated circuit according to a second embodiment. In the second embodiment, a description of the same configuration, operation, and effect as in the first embodiment is omitted by referring to the description described above. The second embodiment differs from the first embodiment in that the selection terminals are combined into one terminal, the external resistors are combined into one resistor, and the selection circuits are combined into one circuit.

A system 502 shown in FIG. 11 includes a battery device 402 and the electronic device 300. The battery device 402 includes the secondary battery 210 and a battery protection device 602. The battery protection device 602 is, for example, a component having a substrate on which at least a protection IC 102 and a resistor R0 are mounted. The protection IC 102 includes, for example, a charge control terminal (terminal COUT), a discharge control terminal (terminal DOUT), a detection terminal (terminal VM), the power supply terminal (terminal VDD), a ground terminal (terminal VSS), a current detection terminal (terminal CS), a selection terminal (terminal SEL0), and a selection circuit 230.

The terminal SEL0 is a terminal for selecting specifications of a first judgment voltage (in this example, the overcharge detection voltage Vdet1 or the over-discharge detection voltage Vdet2) and a second judgment voltage (in this example, the discharging overcurrent detection voltage Vdet3 or the charging overcurrent detection voltage Vdet4). The resistor R0 is externally connected. The resistor R0 is an example of a first resistor provided outside the protection IC 102.

The selection circuit 230 changes a first judgment voltage and a second judgment voltage, according to the resistance value of the resistor R0 that is externally connected to the terminal SEL0. For example, the first judgment voltage may be used as the overcharge detection voltage Vdet1, the second judgment voltage may be used as the charging overcurrent detection voltage Vdet4. Alternatively, the first judgment voltage may be used as the over-discharge detection voltage Vdet2, and the second judgment voltage may be used as the discharging overcurrent detection voltage Vdet3. In the following description of the second embodiment, as one example, the overcharge detection voltage Vdet1 is used as the first judgment voltage, and the charging overcurrent detection voltage Vdet4 is used as the second judgment voltage.

The selection circuit 230 changes the overcharge detection voltage Vdet1 and the charging overcurrent detection voltage Vdet4, according to the resistance value of the resistor R0 externally connected to the terminal SEL0. In this arrangement, the overcharge detection voltage Vdet1 and the charging overcurrent detection voltage Vdet4 can be easily changed by changing the resistance value of the resistor R1 externally connected to the protection IC 102. By using the resistor R0 externally connected to the protection IC 102, the specifications of the overcharge detection voltage Vdet1 and the charging overcurrent detection voltage Vdet4 can be easily changed while the protection IC 102 is mounted on the substrate.

The selection circuit 230 changes the overcharge detection voltage Vdet1 and the charging overcurrent detection voltage Vdet4 to voltage values, corresponding to the resistance value of the resistor R0 externally connected to the terminal SEL0, in accordance with the correspondence relationship that is preset in the selection circuit 230, for example. In this case, by changing the resistance value of the resistor R0 externally connected to the terminal SEL0 to a specified resistance value, the protection IC 102 can be commonly used for products (for example, the battery protection device 602 and the battery device 402) having different required specifications of each of the overcharge detection voltage Vdet1 and the charging overcurrent detection voltage Vdet4. As a result, for example, inventory management can be simplified, and production man-hours can be reduced.

The selection circuit 230 has a potential change circuit that changes a potential (selection potential VSEL0) at the terminal SEL0, according to the resistance value of the resistor R0 externally connected to the terminal SEL0, and each of the overcharge detection voltage Vdet1 and the charging overcurrent detection voltage Vdet4 may be changed to a voltage value corresponding to the selection potential VSEL0. In this arrangement, when the resistance value of the resistor R0 externally connected to the protection IC 102 changes, the selection potential VSEL0 changes, so that the overcharge detection voltage Vdet1 and the charging overcurrent detection voltage Vdet4 can easily change. The selection circuit 230 changes each of the overcharge detection voltage Vdet1 and the charging overcurrent detection voltage Vdet4 to a voltage value corresponding to the selection potential VSEL0, in accordance with a correspondence relationship that is preset in the selection circuit 230, for example.

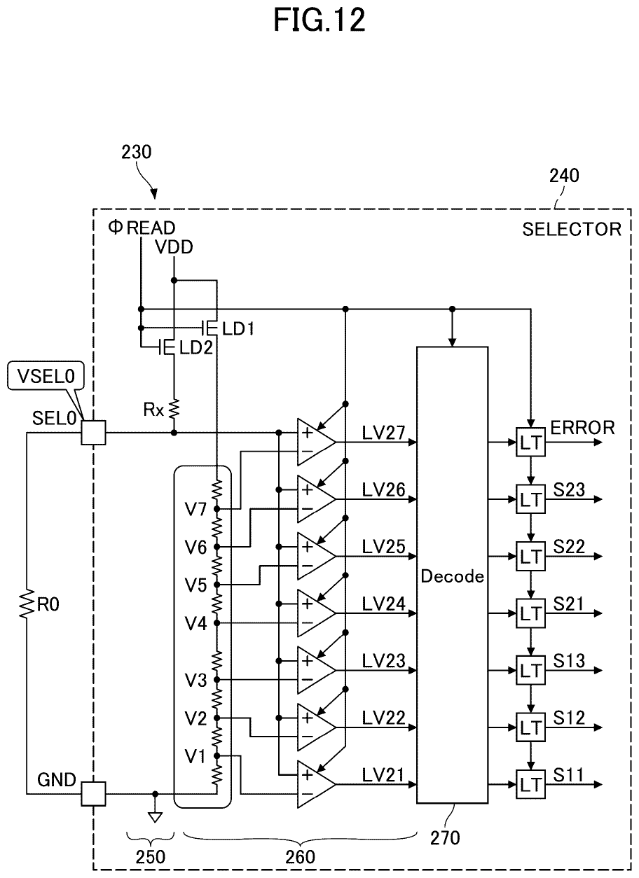

FIG. 12 is a diagram for describing a configuration example of a selector in the selection circuit. The selection circuit 230 includes a selector 240 as a component. When a read signal ΦREAD is in an active state, the selector 240 selects one selection signal corresponding to the resistance value of the resistor R0 externally connected to the terminal SEL0, from among a plurality of different selection signals S11, S12, S13, S21, S22, and S23. These different selection signals S11, S12, S13, S21, S22, and S23 are selection signal candidates that are preset in the decoder 270 in the selector 240.

The selector 240 includes a potential change circuit 250 that changes a potential (selection potential VSEL0) at the terminal SEL0 by using the reference resistor Rx and the switch LD2, according to the resistance value of the resistor R0 externally connected to the terminal SEL0. The reference resistor Rx is inserted in series in a current path between the terminal SEL0 and the terminal VDD. When the switch LD2 is turned on in response to the read signal ΦREAD, the selection terminal SEL1 is pulled up to the terminal VDD through the reference resistor Rx, so that the selection potential VSEL1 changes according to the resistance value of the resistor R0.

The selector 240 includes an encoder 260. The encoder 260 encodes the selection potential VSEL0, and outputs codes (LV21, LV22, LV23, LV24, LV25, LV26, and LV27) corresponding to the resistance value of the resistor R0. The encoder 260 has resistors in series that are inserted in series between the terminal VDD and the terminal VSS, and a plurality of comparators that compare the selection potential VSEL0 with respective potentials V1, V2, V3, V4, V5, V6, and V7. When the switch LD1 is turned on in response to the read signal ΦREAD, the different potentials V1, V2, V3, V4, V5, V6, and V7 are generated by voltage division using the resistors in series.

The selector 240 includes a decoder 270. The decoder 270 is a circuit that converts one or more among the codes (LV21, LV22, LV23, LV24, LV25, LV26, and LV27) into one or more given selection signal among selection signals and an error signal ERROR. The decoder 270 outputs the one or more given selection signals, among the selection signals S11, S12, S13, S21, S22, and S23 and the error signal ERROR, as a result of selecting one or more among the codes (LV21, LV22, LV23, LV24, LV25, LV26, and LV27). The one or more given selection signals, among the selection signals S11, S12, S13, S21, S22, and S23 and the error signal ERROR, that are output from the decoder 270 are held in respective latch circuits LT.

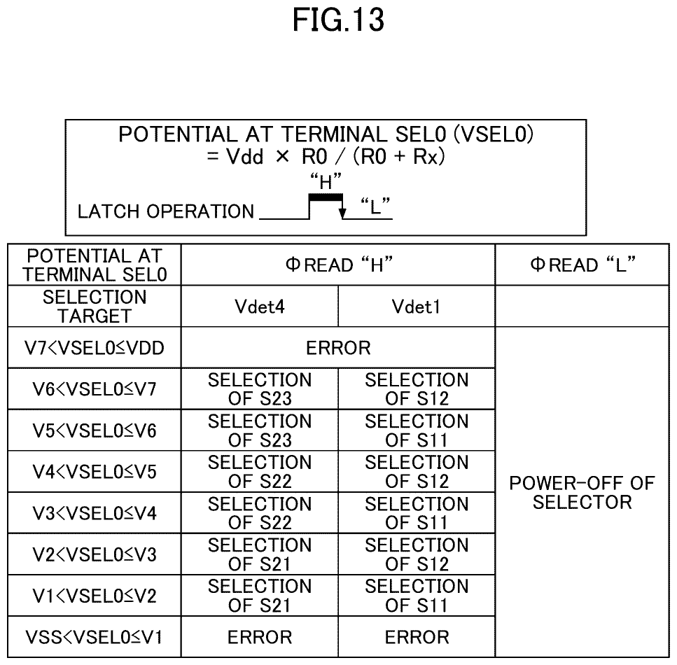

FIG. 13 is a table for describing an operation example of the selector. The selector 240 becomes operational when the read signal ΦREAD is in the active state (in this example, at a high level “H”). In an operational state, the selector 240 outputs, from the decoder 270, result(s) of selecting the selection potential VSEL0 corresponding to the resistance value of the resistor R0 externally connected to the terminal SEL0. When the read signal ΦREAD transitions from the active state to an inactive state (in this example, a low level “L”) in the selector 240, selection result(s) are held in respective latch circuits LT. When overcharging or over-discharging is detected, the read signal ΦREAD can be set as a pulse signal having an active state that is shorter than a time period during which the overcharging or over-discharging is detected. As a result, the effect of power consumption reduction in the protection IC 102 can be effectively improved.

For example, when the selection potential VSEL0 is higher than a potential at the terminal VSS and equal to or less than the potential V1, or higher than a potential V7 and equal to or less than the potential at the terminal VDD, the selector 240 selects the error signal ERROR, and the error signal ERROR is held in the latch circuit LT. When the selection potential VSEL0 is higher than the potential V1 and equal to or less than the potential V2, the selector 240 holds a selected selection signal 511, and a selected selection signal S21 in the respective latch circuits LT. In this arrangement, the selector 240 selects one or more selection signals in accordance with a correspondence relationship shown in FIG. 13, and the one or more selection signals are held in the respective latch circuits LT. In the correspondence relationship shown in FIG. 13, the overcharge detection voltage Vdet1 and the charging overcurrent detection voltage Vdet4 form a pair corresponding to the resistance value of the resistor R0.

Other portions of the selection circuit 230 according to the second embodiment may have the configuration illustrated in FIGS. 6 to 10.

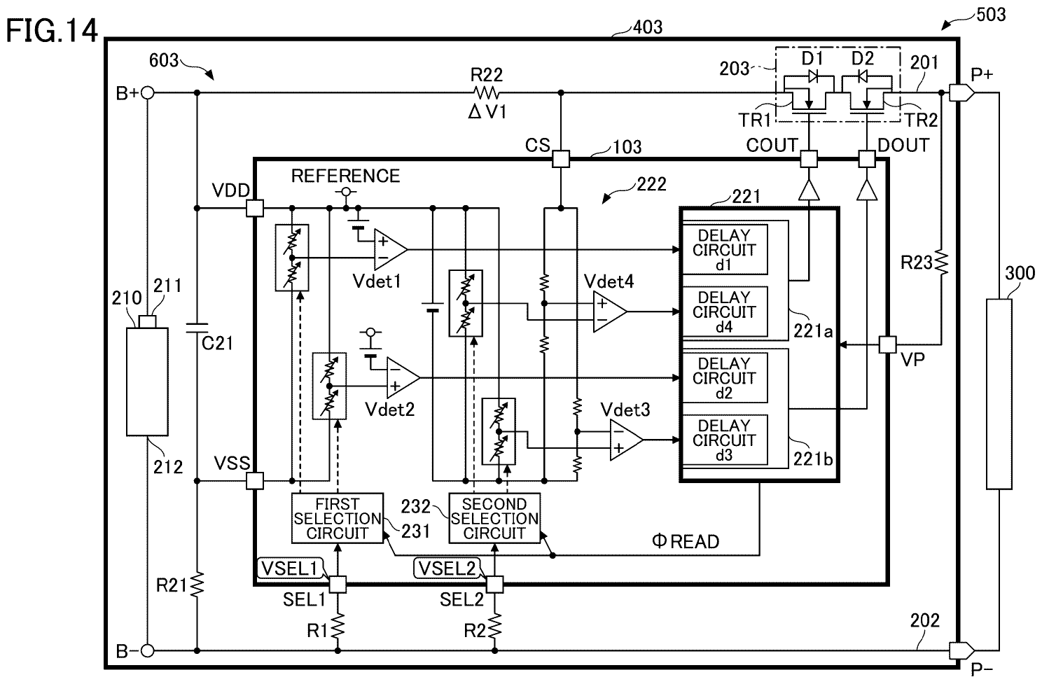

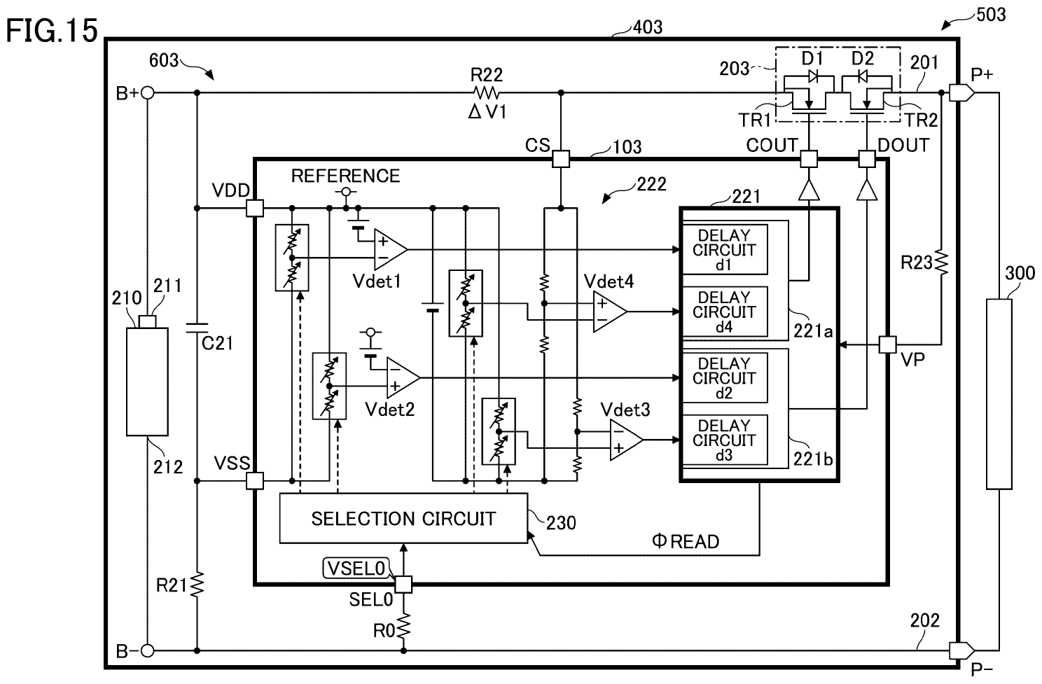

FIG. 14 is a circuit block diagram showing an example of the system including the secondary battery protection integrated circuit according to a third embodiment. In the third embodiment, description of the structure, operation, and effect that are similar to those in the above-described embodiments are omitted by referring to the above-described description. The third embodiment differs from the first embodiment in that the switch circuit 203 is provided on the high-side power line 201. In a modification of the third embodiment, as in the second embodiment, the selection terminals may be combined into one terminal, the resistors may be combined into one resistor, and the selection circuits may be combined into one selection circuit, as shown in FIG. 15.

A system 503 shown in FIG. 14 includes a battery device 403 and the electronic device 300. The battery device 403 includes a secondary battery 210 and a battery protection device 603. The battery protection device 603 is, for example, a component including a substrate on which at least a protection IC 103 and resistors R1 and R2 are mounted. The protection IC 103 includes, for example, a charge control terminal (terminal COUT), a discharge control terminal (terminal DOUT), a detection terminal (terminal VP), a power supply terminal (terminal VDD), a ground terminal (terminal VSS), a current detection terminal (terminal CS), a first selection terminal (terminal SEL1), a second selection terminal (SEL2), a first selection circuit 231, and a second selection circuit 232. The terminal VP has the same function as the terminal VM in the first embodiment.

A detection circuit 222 detects overcharging of the secondary battery 210 by monitoring the power supply voltage Vdd between the terminal VDD and the terminal VSS. The detection circuit 222 compares the power supply voltage Vdd with the overcharge detection voltage Vdet1, and generates an overcharge detection signal indicating that the overcharging of the secondary battery 210 is detected, when the power supply voltage Vdd is higher than the overcharge detection voltage Vdet1.

The detection circuit 222 detects overcharging of the secondary battery 210 by monitoring a potential difference ΔV1 between the terminal VDD and the terminal CS (or the terminal VP). The detection circuit 222 compares the potential difference ΔV1 with the charging overcurrent detection voltage Vdet4, and generates a charging overcurrent detection signal indicating that the overcharge of the secondary battery 210 is detected, when the potential difference ΔV1 is higher than the charging overcurrent detection voltage Vdet4 with reference to the terminal VDD. In other words, the detection circuit 222 generates a charging overcurrent detection signal when the voltage of the terminal CS (or the terminal VP) is higher than the charging overcurrent detection voltage Vdet4 with reference to the terminal VDD.

The detection circuit 222 detects over-discharging of the secondary battery 210 by monitoring the power supply voltage Vdd between the terminal VDD and the terminal VSS. The detection circuit 222 compares the power supply voltage Vdd with the over-discharge detection voltage Vdet2, and generates an over-discharge detection signal indicating that the over-discharging of the secondary battery 210 is detected, when the power supply voltage Vdd is less than the over-discharge detection voltage Vdet2.

The detection circuit 222 detects the discharging overcurrent of the secondary battery 210 by monitoring the potential difference ΔV1 between the terminal VDD and the terminal CS (or the terminal VP). The detection circuit 222 compares the potential difference ΔV1 with the discharging overcurrent detection voltage Vdet3, and generates a discharging overcurrent detection signal indicating that the discharging overcurrent of the secondary battery 210 has been detected when the potential difference ΔV1 is less than the discharging overcurrent detection voltage Vdet3 with reference to the terminal VDD. In other words, the detection circuit 222 generates a discharging overcurrent detection signal when the voltage of the terminal CS (or the terminal VP) is less than the discharging overcurrent detection voltage Vdet3 with reference to the terminal VDD.

Although the embodiments have been described above, the above embodiments are presented by way of examples, and the present disclosure is not limited to the above embodiments. The above embodiments may be embodied in various other forms, and various combinations, omissions, substitutions, modifications, or the like may be made without departing from the gist of the disclosure. These embodiments, their modifications, and equivalents are intended to cover the scope and gist of the disclosure.

For example, arrangement positions of the charge control transistor TR1 and the discharge control transistor TR2 may be mutually replaced with respect to the positions shown in the drawings. The switch circuit 203 may be incorporated into the protection IC.

The secondary battery protection integrated circuit may select a circuit characteristic, or a function, different from at least one judgment voltage, based on a resistance value of a resistor externally connected to a selection terminal by the same configuration or method as the configuration or method described above for selecting the judgment voltage, such as the overcharge detection voltage Vdet1. Examples of the circuit characteristic different from the judgment voltage include a delay time, such as the detection delay time d1.

With respect to the above embodiments, the following additional items are disclosed.

### (Item 1)

A first judgment voltage and a second judgment voltage form a pair corresponding to a resistance value of a first resistor.

### (Item 2)

A first judgment voltage can be adjusted to any one of k voltage values. Here, the number of trimming elements is a natural number multiple of k.

In the present disclosure, circuit characteristics, such as a judgment voltage, can be modified easily.

What is claimed is:

1. A secondary battery protection integrated circuit comprising:
a plurality of terminals including a power supply terminal, a ground terminal, a selection terminal, and a control terminal;
a selection circuit configured to change a judgment voltage according to a resistance value of a resistor that is configured to be externally coupled to the selection terminal; and
a control circuit configured to output a signal to control charging or discharging of a secondary battery to the control terminal, based on comparing a power supply voltage between the power supply terminal and the ground terminal, with the judgment voltage.

2. A secondary battery protection integrated circuit comprising:
a plurality of terminals including a power supply terminal, a ground terminal, a selection terminal, a monitor terminal, and a control terminal;
a selection circuit configured to change a judgment voltage according to a resistance value of a resistor that is configured to be externally coupled to the selection terminal; and
a control circuit configured to output a signal to control charging or discharging of a secondary battery to the control terminal, based on comparing, with the judgment voltage, either a first potential difference between the monitor terminal and the power supply terminal or a second potential difference between the monitor terminal and the ground terminal.

3. A secondary battery protection integrated circuit comprising:
a plurality of terminals including a power supply terminal, a ground terminal, a first selection terminal, a second selection terminal, a monitor terminal, and at least one control terminal;
a selection circuit configured to
change at least one first judgment voltage according to a resistance value of a first resistor that is configured to be externally coupled to the first selection terminal, and
change at least one second judgment voltage according to a resistance value of a second resistor that is configured to be externally coupled to the second selection terminal; and
a control circuit configured to
output a first signal to control charging or discharging of a secondary battery to the control terminal, based on comparing a power supply voltage between the power supply terminal and the ground terminal, with the first judgment voltage, and
output a second signal to control the charging or the discharging of the secondary battery to the control terminal, based on comparing, with the second judgment voltage, either a first potential difference between the monitor terminal and the power supply terminal or a second potential difference between the monitor terminal and the ground terminal.

4. A secondary battery protection integrated circuit comprising:
a plurality of terminals including a power supply terminal, a ground terminal, a first selection terminal, a second selection terminal, a monitor terminal, and at least one control terminal;
a selection circuit configured to change at least one first judgment voltage and at least one second judgment voltage, according to a resistance value of a resistor that is configured to be externally coupled to the selection terminal; and
a control circuit configured to
output a signal to control charging or discharging of a secondary battery to the control terminal, based on comparing a power supply voltage between the power supply terminal and the ground terminal, with the first judgment voltage, and
output a signal to control the charging or the discharging of the secondary battery to the control terminal, based on comparing, with the second judgment voltage, either a first potential difference between the monitor terminal and the power supply terminal or a second potential difference between the monitor terminal and the ground terminal.

5. The secondary battery protection integrated circuit according to claim 1, wherein the control circuit is configured to output the signal to stop the charging of the secondary battery upon occurrence of a condition in which the power supply voltage is higher than the judgment voltage.

6. The secondary battery protection integrated circuit according to claim 1, wherein the control circuit is configured to output the signal to stop the discharging of the secondary battery upon occurrence of a condition in which the power supply voltage is less than the judgment voltage.

7. The secondary battery protection integrated circuit according to claim 2, wherein the control circuit is configured to output the signal to stop the charging of the secondary battery upon occurrence of a condition in which the first potential difference is higher than the judgment voltage with reference to the power supply terminal.

8. The secondary battery protection integrated circuit according to claim 2, wherein the control circuit is configured to output the signal to stop the discharging of the secondary battery upon occurrence of a condition in which the first potential difference is less than the judgment voltage with reference to the power supply terminal.

9. The secondary battery protection integrated circuit according to claim 2, wherein the control circuit is configured to output the signal to stop the discharging of the secondary battery upon occurrence of a condition in which the second potential difference is higher than the judgment voltage with reference to the ground terminal.

10. The secondary battery protection integrated circuit according to claim 2, wherein the control circuit is configured to output the signal to stop the charging of the secondary battery upon occurrence of a condition in which the second potential difference is less than the judgment voltage with reference to the ground terminal.

11. The secondary battery protection integrated circuit according to claim 3,
wherein the at least one first judgment voltage includes a first detection voltage and a second detection voltage,
wherein the at least one second judgment voltage includes a third detection voltage and a fourth detection voltage,
wherein the at least one control terminal includes a charge control terminal and a discharge control terminal, and
wherein the control circuit is configured to
output a signal to stop the charging of the secondary battery to the charge control terminal, upon occurrence of a condition in which the power supply voltage is higher than the first detection voltage,
output a signal to stop the discharging of the secondary battery to the discharge control terminal, upon occurrence of a condition in which the power supply voltage is less than the second detection voltage,
output a signal to stop the discharging of the secondary battery to the discharge control terminal, upon occurrence of a condition in which the first potential difference is less than the third detection voltage with reference to the power supply terminal, or the second potential difference is higher than the third detection voltage with reference to the ground terminal, and
output a signal to stop the charging of the secondary battery to the charge control terminal, upon occurrence of a condition in which the first potential difference is higher than the fourth detection voltage with reference to the power supply terminal, or the second potential difference is less than the fourth detection voltage with reference to the ground terminal.

12. The secondary battery protection integrated circuit according to claim 1, wherein the selection circuit is configured to output an error signal upon occurrence of a condition in which the resistance value of the resistor is greater than a first threshold or less than a second threshold, and
wherein the control circuit is configured to output the signal to stop the charging or the discharging of the secondary battery, in accordance with the error signal.

13. The secondary battery protection integrated circuit according to claim 2, wherein the selection circuit is configured to output an error signal upon occurrence of a condition in which the resistance value of the resistor is greater than a first threshold or less than a second threshold, and
wherein the control circuit is configured to output the signal to stop the charging or the discharging of the secondary battery from the control terminal, in accordance with the error signal.

14. The secondary battery protection integrated circuit according to claim 1, wherein the selection circuit includes
a plurality of trimming elements;
a selector configured to select elements corresponding to the resistance value of the resistor, from among the plurality of trimming elements; and
an adjustment circuit configured to adjust the judgment voltage to a voltage value corresponding to trimming states of the elements selected by the selector.

15. The secondary battery protection integrated circuit according to claim 2, wherein the selection circuit includes
a plurality of trimming elements,
a selector configured to select elements corresponding to the resistance value of the resistor, from among the plurality of trimming elements, and
an adjustment circuit configured to adjust the judgment voltage to a voltage value corresponding to trimming states of the elements selected by the selector.

16. The secondary battery protection integrated circuit according to claim 1, wherein the selection circuit includes
a selector configured to select a selection signal corresponding to the resistance value of the resistor, upon occurrence of a condition in which a read signal is in an active state,
a holding circuit configured to hold the selection signal selected by the selector, and
an adjustment circuit configured to adjust the judgment voltage to a voltage value corresponding to the selection signal held in the holding circuit,
wherein the selection circuit is configured to interrupt current supply to the selector, upon occurrence of a condition in which the read signal is in an inactive state.

17. The secondary battery protection integrated circuit according to claim 16, wherein the read signal is configured to become active under a condition in which over-discharging of the secondary battery is detected, and
wherein the read signal is configured to become inactive under a condition in which the over-discharging is not detected.

18. The secondary battery protection integrated circuit according to claim 2, wherein the selection circuit includes
a selector configured to select a selection signal corresponding to the resistance value of the resistor, upon occurrence of a condition in which a read signal is in an active state,
a holding circuit configured to hold the selection signal selected by the selector, and
an adjustment circuit configured to adjust the judgment voltage to a voltage value corresponding to the selection signal held in the holding circuit, and
wherein the selection circuit is configured to interrupt current supply to the selector, upon occurrence of a condition in which the read signal is in an inactive state.

19. The secondary battery protection integrated circuit according to claim 18, wherein upon occurrence of a condition in which over-discharging of the secondary battery is detected, the read signal is configured to be set to have the inactive state that is shorter than a time period during which the over-discharging is detected.

20. A battery device comprising:
the secondary battery protection integrated circuit of claim 1; and
the secondary battery.
